(19) United States
(12) Patent Application Publication
(10) Pub. No.: US 2026/0173561 A1
(43) Pub. Date: Jun. 18, 2026

(54) IMAGE SENSOR PIXEL WITH PIXEL ISOLATION

(71) Applicant: Taiwan Semiconductor Manufacturing Company, LTD., Hsinchu (TW)

(72) Inventors: Bo-Yuan Su, Hsinchu (TW); Min-Feng Kao, Chiayi (TW); Yen-Ting Chiang, Tainan (TW); Jen-Cheng Liu, Hsinchu (TW)

(21) Appl. No.: 18/980,112

(22) Filed: Dec. 13, 2024

(51) Int. Cl. H10F 39/00

(52) U.S. Cl. CPC H10F 39/807; H10F 39/014; H10F 39/026

(57) ABSTRACT

An image sensor pixel includes a light sensor disposed in a semiconductor substrate. To provide isolation to reduce interpixel crosstalk and increase Modulation Transfer Function (MTF), an etch stop is disposed on a first surface of the semiconductor substrate, and a deep trench is etched from an opposite second surface to the etch stop disposed on the first surface. The etching stops at the etch stop, and a bottom surface of the etched deep trench is a surface of the etch stop. At least one dielectric layer may be deposited on a sidewall and the bottom surface of the deep trench, and the remainder of the deep trench is filled with a metal or other opaque material. An image sensor pixel includes a semiconductor substrate and a photodiode disposed therein, and a metal barrier passing through the semiconductor substrate and arranged to provide optical isolation of the photodiode.

### BACKGROUND

The following relates to image sensors, manufacturing of image sensors, CMOS image sensor (CIS) technology, and the like.

An image sensor comprises an array of image sensor pixels, each including a photodiode or other light sensor. In some designs, the wafer may be thinned to match the light absorption profile, and the (optionally thinned) wafer containing the CIS may be bonded to a second wafer on which associated electronics are fabricated.

Image sensor resolution is controlled by the size of the image sensor pixels, that is, smaller image sensor pixels enable a higher number and density of image sensor pixels to be disposed in the active image sensor area. However, as the image sensor pixels are made smaller, crosstalk (optical and/or electrical) between neighboring image sensor pixels becomes an increasingly challenging problem. Modulation Transfer Function (MTF) is a commonly used metric for assessing performance of an image sensor. The MTF characterizes how well the contrast of an object is maintained by the image captured by the image sensor. For an image sensor with given pixel resolution, the MTF can be viewed as a metric of the extent of crosstalk between neighboring image sensor pixels, with higher MTF being desirable as it is indicative of reduced crosstalk.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A diagrammatically illustrates a cut view of an image sensor pixel according to an embodiment.

FIG. 1B diagrammatically illustrates a cut view of an image sensor pixel according to an embodiment.

FIGS. 2A, 2B, 2C, 2D, 2E, 2F, and 2G diagrammatically illustrate a method of fabricating an image sensor pixel by way of successive cut views.

FIG. 3 diagrammatically illustrates a cut view of an image sensor pixel according to another embodiment.

FIG. 4 diagrammatically illustrates a cut view of an image sensor pixel according to another embodiment.

FIG. 5 diagrammatically illustrates top and cut views of the image sensor pixel of FIGS. 1 and 2G in the context of a two-wafer stack according to an embodiment.

FIG. 6 diagrammatically illustrates top and cut views of the image sensor pixel of FIGS. 1 and 2G in the context of a two-wafer stack according to an embodiment.

FIGS. 7A, 7B, 7C, 7D, and 7E diagrammatically illustrate a method of fabricating the two-wafer stack of FIG. 6.

FIG. 8 diagrammatically illustrates top and cut views of the image sensor pixel of FIGS. 1 and 2G in the context of a three-wafer stack according to an embodiment.

### DETAILED DESCRIPTION

The following disclosure provides many different embodiments, or examples, for implementing different features of the provided subject matter. Specific examples of components and arrangements are described below to simplify the present disclosure. These are merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

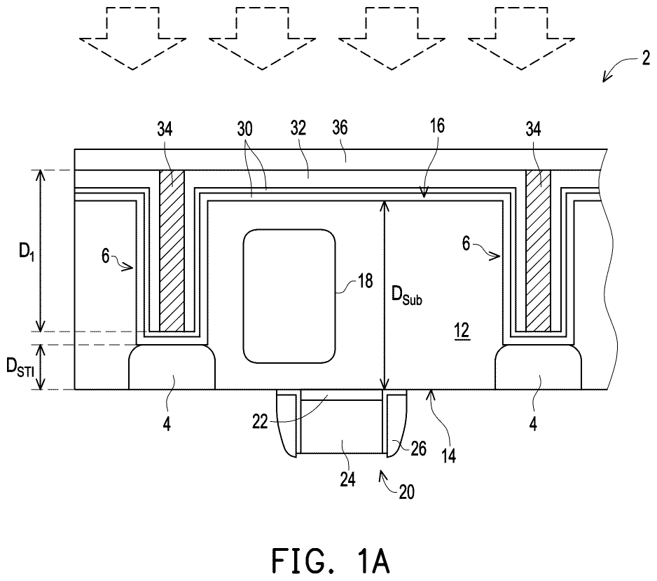

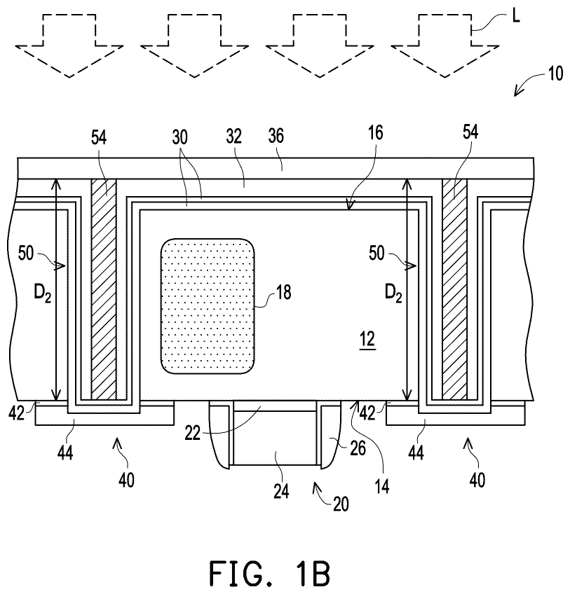

With reference to FIG. 1A, a cut view is diagrammatically shown of an image sensor pixel 2 according to one embodiment, formed in and/or on a semiconductor substrate 12, which has a first surface 14 and second surface 16 on opposite sides of the semiconductor substrate 12. The first surface 14 is also sometimes referred to herein as a front surface or front side 14, and the second surface 16 is also sometimes referred to herein as a back surface or backside 16. In the nonlimiting illustrative example, the image sensor pixel 2 is designed for back-side illumination in which light L impinges on the backside 16. The semiconductor substrate 12 is made of a semiconductor material, such as silicon, gallium phosphide (GaP), gallium arsenide (GaAs), or so forth. The illustrative semiconductor substrate 12 is made of a single material, which in illustrative examples herein is silicon. However, as noted other semiconductor materials are contemplated, and moreover the semiconductor substrate may optionally comprise multiple materials, such as (by way of one nonlimiting illustrative example) comprising a silicon wafer with one or more heteroepitaxial semiconductor layers such as one or more silicon-germanium alloy layers with germanium composition x (i.e., one or more Si₁₋ₓGeₓ layers) disposed thereon. The choice of semiconductor material (or materials) for the semiconductor substrate 12 is suitably made based on design factors such as matching the bandgap or other absorption characteristic(s) of the semiconductor material with a wavelength or wavelength band or region of light to be detected by the image sensor pixel 2. The semiconductor substrate 12 has a thickness D_{Sub} between the surfaces 14 and 16, as indicated in FIG. 1A. In some nonlimiting illustrative embodiments, the semiconductor substrate 12 may comprise a silicon wafer that has been thinned to a reduced thickness, such as D_{sub}=5-8 microns in a nonlimiting illustrative example, so that substrate thickness D_{sub} approximately matches the light absorption depth of light to be imaged and minimizes the thickness of the image sensor.

The image sensor pixel 2 is an illustrative pixel of a two-dimensional array of such pixels forming an image sensor. In one nonlimiting illustrative example, the image sensor may be manufactured in complementary metal-oxide-semiconductor (CMOS) technology, in which case it may be referred to as a CMOS image sensor (CIS). Each CIS pixel 2 includes an image sensing element 18 that is configured to receive incident light comprising photons, and an electronic readout device or subcircuit, for example comprising a CMOS transistor 20. The illustrative light sensor 18 is disposed in the semiconductor substrate 12. The light sensor 18 may be a photodiode, a photosensitive capacitor, or other electronic device that converts light to an electrical signal. In one nonlimiting illustrative embodiment, the semiconductor substrate 12 is silicon and the light sensor 18 is a silicon, germanium, and/or Si₁₋ₓGeₓ photodiode formed by dopant implantation and/or diffusion to form a p/n junction, heteroepitaxy to form a heterojunction, and/or other fabrication techniques. The light sensor 18 is designed to detect light at the wavelength or in the wavelength band or region of light to be imaged by an array of the image sensor pixels 2. The wavelength or wavelength band or region of light may include a portion or all of the visible light spectrum, a portion or all of the ultraviolet spectrum, a portion or all of the infrared spectrum, a combination thereof (e.g., in the case of a visible-near infrared image sensor), or so forth. The illustrative image sensor pixel 2 of FIG. 1A further includes an electronic readout device or subcircuit 20, which is operatively connected with the light sensor 18 to transfer and/or modify and/or convert the electrical signal generated by the light sensor 18 in response to the light to an output of the sensor pixel. In the nonlimiting illustrative embodiment, the electronic readout device or subcircuit 20 includes a CMOS transistor, illustrated in FIG. 1A by a gate dielectric 22 and gate 24, and illustrative oxide/silicon nitride spacers 26. In one nonlimiting illustrative example, the semiconductor substrate 12 is a silicon substrate, the electronic readout device or subcircuit 20 is a MOSFET or MOSFET-based readout sub-circuit, and the image sensor pixels are CMOS image sensor (CIS) pixels.

With reference to FIG. 1B, a cut view is diagrammatically shown of an image sensor pixel 10 according to another embodiment, again formed in and/or on the semiconductor substrate 12 with the first (e.g., front) and second (e.g., back) surfaces 14 and 16 as previously described for FIG. 1A. The image sensor pixel 10 is designed for back-side illumination in which light L impinges on the backside 16. The semiconductor substrate 12 again has the thickness D_{Sub} between the surfaces 14 and 16, as indicated in FIG. 1B. As with the embodiment of FIG. 1A, in some nonlimiting illustrative embodiments the semiconductor substrate 12 may comprise a silicon wafer that has been thinned to a reduced thickness, such as D_{sub}=5-8 microns in a nonlimiting illustrative example, so that substrate thickness D_{sub} approximately matches the light absorption depth of light to be imaged and minimizes the thickness of the image sensor.

The image sensor pixel 10 of FIG. 1B is an illustrative pixel of a two-dimensional array of such pixels forming an image sensor. In one nonlimiting illustrative example, the image sensor may be manufactured in CMOS technology and be referred to as a CMOS image sensor (CIS). Each CIS pixel 10 includes an image sensing element 18 (e.g., a photodiode, a photosensitive capacitor, or other electronic device that converts light to an electrical signal) as previously described for the embodiment of FIG. 1A, that is configured to receive incident light comprising photons, and an electronic readout device or subcircuit, for example comprising a CMOS transistor 20. In one nonlimiting illustrative embodiment, the semiconductor substrate 12 is silicon and the light sensor 18 is a silicon, germanium, and/or Si₁₋ₓGeₓ photodiode formed by dopant implantation and/or diffusion to form a p/n junction, heteroepitaxy to form a heterojunction, and/or other fabrication techniques. The light sensor 18 is designed to detect light at the wavelength or in the wavelength band or region of light to be imaged by an array of the image sensor pixels 10. The wavelength or wavelength band or region of light may include a portion or all of the visible light spectrum, a portion or all of the ultraviolet spectrum, a portion or all of the infrared spectrum, a combination thereof (e.g., in the case of a visible-near infrared image sensor), or so forth. The illustrative image sensor pixel 10 of FIG. 1B again includes an electronic readout device or subcircuit 20, which is operatively connected with the light sensor 18 to transfer and/or modify and/or convert the electrical signal generated by the light sensor 18 in response to the light to an output of the sensor pixel. In the nonlimiting illustrative embodiment of FIG. 1B, the electronic readout device or subcircuit 20 is a CMOS transistor, illustrated in FIG. 1B by a gate dielectric 22 and gate 24, and illustrative oxide/silicon nitride spacers 26. In one nonlimiting illustrative example, the semiconductor substrate 12 is a silicon substrate, the electronic readout device or subcircuit 20 is a MOSFET or MOSFET-based readout sub-circuit, and the image sensor pixels are CMOS image sensor (CIS) pixels.

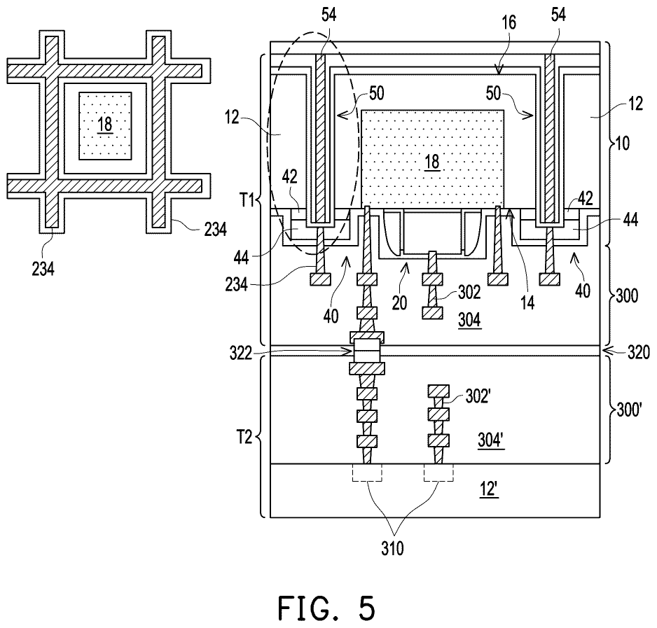

With continuing reference to FIGS. 1A and 1B, in one nonlimiting illustrative example, the electronic readout device or subcircuit 20 includes a transfer gate 20 and associated circuitry (not shown). During an exposure time interval for acquiring an image (for example, set by a shutter speed in the case of a digital camera), photocharge is accumulated at each pixel 2 or 10, and more particularly at the photodiode or other light sensor 18 of each pixel. At the end of the exposure, the accumulated photocharge of the light sensor 18 of each pixel 2 or 10 is transferred out (i.e., read) via one or more transfer gates. This is to be understood to be one nonlimiting example, and a wide range of readout circuitry can be employed in the CIS or other image sensor depending on design considerations. It is also to be understood that some portion of the readout circuitry may be disposed on a second wafer or chip bonded to the semiconductor substrate 12. Some nonlimiting illustrative examples of such multichip CIS or other image sensor designs are described herein with reference to FIGS. 5, 6, and 8.

It will be appreciated that the two illustrative image sensor pixels 2 and 10 of respective FIGS. 1A and 1B are representative—in implementation, the image sensor includes a two-dimensional array of image sensor pixels 2; or the image sensor includes a two-dimensional array of image sensor pixels 10. Although not shown in FIGS. 1A and 1B (but see FIGS. 5, 6, and 8 and related description hereinbelow), a metallization layer or stack may be disposed on the frontside 14 of the image sensor comprising the two-dimensional array of image sensor pixels to provide electrical transmission pathways for the pixel outputs of the electronic readout device or subcircuits 20 of the image sensor pixels. In the example of a CIS image sensor, the electronic readout device or subcircuits 20 of the image sensor pixels 2 and 10 and the signal output metallization layer or stack are suitably fabricated using CMOS fabrication techniques. Furthermore, the image sensor pixels may include other features not shown. For example, one or more light-coupling and/or light-shaping components or features may be disposed on the light-receiving second surface 16, such as a lens or microlens, and/or a color filter, and/or an anti-reflection coating on the light-receiving second surface 16, and/or a roughening and/or texturing of the light-receiving second surface 16). An optional lens or microlens may be provided to focus light onto the light sensor 18. An optional color filter may be provided to pass light in a particular wavelength band while blocking unwanted light outside of this wavelength band. As a more specific nonlimiting illustrative example, in a red-green-blue (RGB) imaging array, the image sensor pixels 2 or 10 may be grouped into color pixels, with each color pixel comprising: an image sensor pixel 2 or 10 with a red filter; an image sensor pixel 2 or 10 with a blue filter; and an image sensor pixel 2 or 10 with a green filter. In some RGB imaging array designs, there may be additional “color” components in each color pixel, such as an image sensor pixel 2 or 10 with a clear filter, or with no filter. As another nonlimiting illustrative example of further components that may be included, a grid may be disposed on the light-receiving surface 16, with gridlines extending between neighboring image sensor pixels 2 or 10 of a two-dimensional array of image sensor pixels forming a CIS or other image sensor. The grid comprises an opaque material, and reduces optical crosstalk between neighboring image sensor pixels 2 or 10 of the two-dimensional array of image sensor pixels. The grid may be formed, in one nonlimiting illustrative example, by depositing and patterning a metal layer and/or a dielectric layer to form gridlines running between the pixels.

As previously noted, image sensor resolution is controlled by the size of the image sensor pixels 2 or 10 of respective FIG. 1A or 1B making up the two-dimensional array, with smaller image sensor pixels enabling a higher number and density of image sensor pixels to be disposed in a given active image sensor area. However, as the image sensor pixels 2 or 10 are made smaller, crosstalk (optical and/or electrical) between neighboring image sensor pixels becomes an increasingly challenging problem. Optical crosstalk refers to light impinging on one image sensor pixel leaking into neighboring image sensor pixels, while electrical crosstalk refers to photocharge (i.e., electrons or holes generated by impingement of the light L) in the light sensor 18 of one image sensor pixel leaking into neighboring image sensor pixels. Optical and/or electrical crosstalk smears the image content across pixels, thus degrading how well the contrast of an object is maintained by the image captured by the image sensor, and hence reducing the value of the MTF. Suppressing crosstalk, conversely, improves maintenance of the contrast of an object by the image captured by the image sensor, and hence increases the MTF. As previously mentioned, a grid (not shown) disposed on the light-receiving surface 16 with gridlines running between neighboring pixels is one way to reduce optical crosstalk. However, such a surface grid does not block optical crosstalk via light transmitted laterally through the semiconductor substrate 12.

With continuing reference to FIGS. 1A and 1B, deep trench isolation formed in the semiconductor substrate 12 may be provided to reduce crosstalk via light transmitted laterally through the semiconductor substrate 12. The respective illustrative image sensor pixels 2 and 10 of respective FIGS. 1A and 1B illustrate two alternative approaches for providing deep trench isolation that suppresses crosstalk between neighboring image sensor pixels. In the approach of image sensor pixel 2 of FIG. 1A, a region 4 of shallow trench isolation (STI; that is, STI region 4 or STI 4) is formed in the front surface 14 of the semiconductor substrate 12. To form the STI region 4, a shallow trench of depth D_{STI} indicated in FIG. 1A is etched in the front surface 14 of the semiconductor substrate 12, followed by deposition of an oxide layer that fills the shallow trench to form the STI region 4 to the depth D_{STI}, and chemical mechanical polishing (CMP) to remove any excess oxide that may deposit on the front surface 14 of the semiconductor substrate 12. The STI region 4 serves as an etch stop for forming STI-stopped deep trench isolation (DTI) 6 for isolating the image sensor pixel 2. To form the STI-stopped DTI 6, an STI-stopped deep trench is etched from the second (e.g., back) surface 16 of the semiconductor substrate 12, e.g., using dry etching. The dry etching is stopped before it reaches the first (e.g., front) surface 14 of the semiconductor substrate 12 by the STI 4—that is, the STI 4 serves as an etch stop for the etching forming the STI-stopped deep trench. The STI-stopped deep trench at this stage is open at the second (e.g., back) surface 16 of the semiconductor substrate 12. The bottom and sidewall of the STI-stopped deep trench is then coated with one or more dielectric layers (e.g., in the nonlimiting illustrative example, one or more high-k layers 30 and an oxide layer 32) that also coat the second surface 16 of the semiconductor substrate 12, and is then filled with a metal 34 such as electroplated copper or aluminum deposited by physical vapor deposition (PVD). The one or more high-k layers 30 comprise one or more dielectric materials having a dielectric constant higher than the dielectric constant of SiO₂. In some embodiments, the oxide layer 32 is formed by atomic layer deposition (ALD). In the illustrative example, an additional oxide layer 36 is deposited, for example by low-temperature remote plasma-assisted oxidation (LRPO), for example to provide water resistance for the light-receiving surface 16.

The one or more dielectric layers 30, 32 are usually thin compared with the semiconductor substrate 12. In some nonlimiting illustrative examples, the substrate thickness D_{Sub} is about 5-8 microns, while the dielectric layers 30, 32 have thickness in a range of nanometers to tens of nanometers. As labeled in FIG. 1A, the STI-stopped DTI 6 has a depth D₁, and the STI region 4 has depth D_{STI}. Neglecting the thicknesses of the (usually thin) dielectric layers 30, 32, the thickness D₁ of the STI-stopped DTI 6 is the difference between the substrate thickness D_{Sub} and the STI depth D_{STI}, that is, D₁≅D_{Sub}−D_{STI}. While the STI region 4 comprises silicon oxide and hence provides good electrical isolation, the silicon oxide is optically translucent or transparent at least in the visible, near-infrared, and near-ultraviolet spectral regions. Hence, the STI region 4 presents a gap in the optical isolation of dimension D_{STI}. In some nonlimiting examples of CMOS fabrication, the STI depth D_{STI} may be in a range of about 0.2 micron to 0.5 micron—if the substrate thickness D_{Sub} is about 5-8 microns, then D_{STI} is between about 2.5% and about 10% of the total thickness D_{Sub} of the substrate. As recognized herein, this gap in the optical isolation provided by the deep trench isolation of the image sensor pixel 2 reduces effectiveness of the optical isolation, leading to increased crosstalk between image sensor pixels and lower MTF for the image sensor.

With reference now to FIG. 1B, in the isolation approach of image sensor pixel 10, the STI region 4 is replaced by an etch stop 40 which is disposed on the first surface 14 of the semiconductor substrate 12. The isolation approach of image sensor pixel 10 does not include etching a trench in the first surface 14 of the semiconductor substrate 12 (whereas formation of the STI 4 of the isolation of the image sensor pixel 2 does involve etching a shallow trench which is filled to form the STI 4). In the illustrative example of FIG. 1B, the etch stop 40 includes at least one dielectric layer (and in the nonlimiting illustrative example of FIG. 1B, two dielectric layers 42 and 44) on the first surface 14 of the semiconductor substrate 12. In the nonlimiting illustrative example of FIG. 1B, these include an oxide layer 42 disposed on the first surface 14 of the semiconductor substrate 12, and a silicon nitride layer 44 deposited on the oxide layer 42. The etch stop 40 serves as an etch stop for forming a deep trench isolation (DTI) 50 for isolating the image sensor pixel 10. To form the DTI 50, a deep trench is etched from the second (e.g., back) surface 16 of the semiconductor substrate 12, e.g., using dry etching. The dry etching is stopped by the etch stop 40, so that the bottom of the deep trench coincides (or nearly coincides) with the first (e.g., front) surface 14 of the semiconductor substrate 12. Put another way, the etch stop 40 serves as an etch stop for the etching that forms the deep trench. The deep trench passes completely through the semiconductor substrate 12 from the second surface 16 to the first surface 14. The deep trench at this stage is open at the second (e.g., back) surface 16 of the semiconductor substrate 12. The bottom and sidewall of the deep trench is then coated with one or more dielectric layers (e.g., in the nonlimiting illustrative example, the one or more high-k layers 30 and the oxide layer 32) that also coat the second surface 16 of the semiconductor substrate 12. The deep trench is then filled with a metal 54 such as electroplated copper or aluminum deposited by PVD. As previously mentioned, the one or more high-k layers 30 comprise one or more dielectric materials having a dielectric constant higher than the dielectric constant of SiO₂, and in some embodiments the oxide layer 32 is formed by ALD. In the illustrative example, the additional oxide layer 36 is deposited, for example by LRPO, for example to provide water resistance for the light-receiving surface 16.

As previously noted, the one or more dielectric layers 30, 32 are usually thin compared with the thickness D_{Sub} of the semiconductor substrate 12, which in some nonlimiting illustrative embodiments is about 5-8 microns. As labeled in FIG. 1B, the DTI 50 has a depth D₂. The illustrative DTI 50 passes completely through the semiconductor substrate 12 from the second surface 16 to the first surface 14, and in the illustrative example also includes a small additional portion coinciding with the combined thickness of the one or more dielectric layers 30, 32. Hence, the depth D₂ of the DTI 50 is greater than or equal to the thickness D_{Sub} of the substrate 12. Put another way, D₂≥D_{Sub}.

As previously noted, the STI region 4 of the image sensor pixel 2 presents a gap in the optical isolation of dimension D_{STI}. The metal 34 of the STI-stopped DTI 6 has depth D₁ which is limited by the thickness D_{STI} of the STI region 4. In some nonlimiting illustrative embodiments, the STI depth D_{STI} is between about 2.5% and about 10% of the total thickness D_{Sub} of the substrate. Correspondingly, the depth D₁ of the STI-stopped DTI 6 is limited to about 90-98% of the thickness D_{Sub} of the semiconductor substrate 12. By contrast, the DTI 50 passes completely through the semiconductor substrate 12 from the second surface 16 to the first surface 14, advantageously providing improved isolation for suppressing optical cross-talk between neighboring image sensor pixels, and improving (i.e., increasing) the MTF for the image sensor.

The embodiment of FIG. 1B does not employ the STI regions 4 of the embodiment of FIG. 1A to serve as stops for forming the DTI 50. In some implementations of the embodiment of FIG. 1B, the CIS or other two-dimensional array of image sensor pixels making up an image sensor may include no STI regions at all. This can be advantageous as formation of STI regions entails a number of fabrication steps, such as photolithographically controlled dry etching to form shallow trenches in the front side 14, subsequent thermal oxidation to fill the shallow trenches with oxide material thus forming the STI regions, followed by chemical mechanical polishing (CMP) to remove the excess thermal oxide from the front side 14. In other implementations of the embodiment of FIG. 1B, the CIS or other two-dimensional array of image sensor pixels making up an image sensor may include STI regions (not shown) for other purposes besides serving as a stop for the formation of the deep trench isolation.

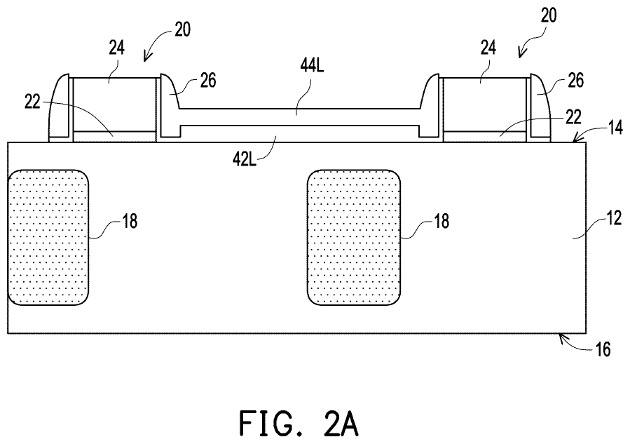

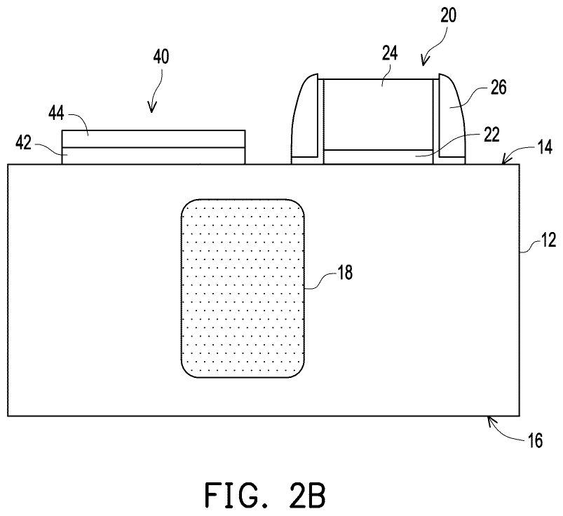

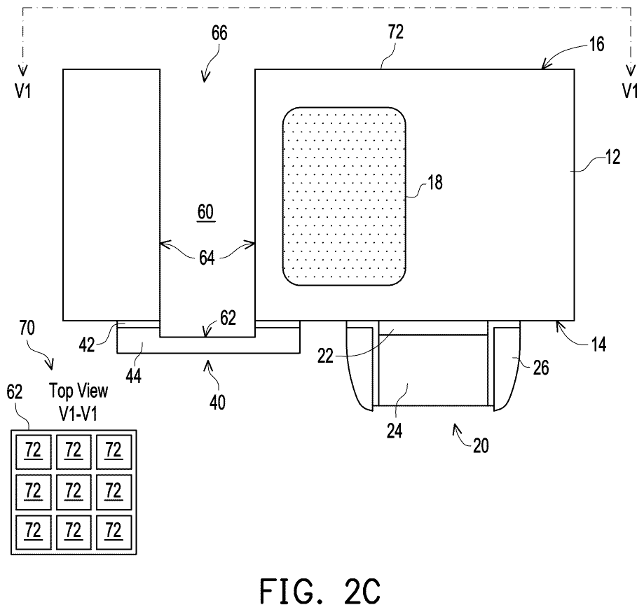

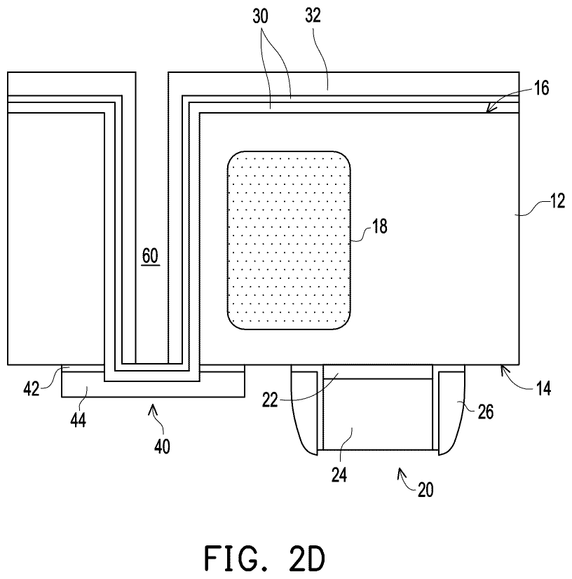

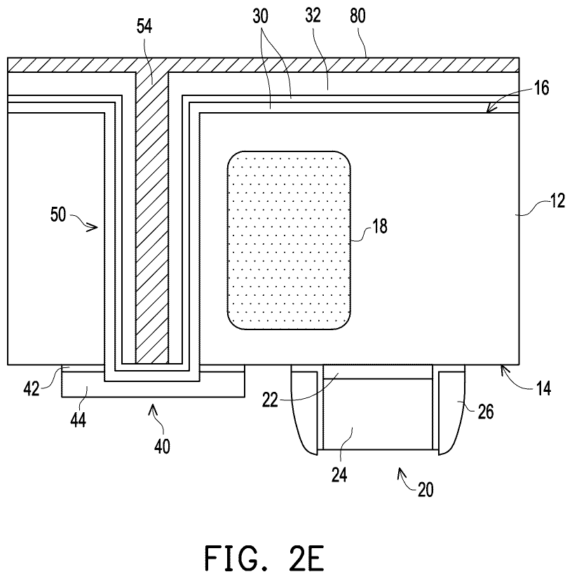

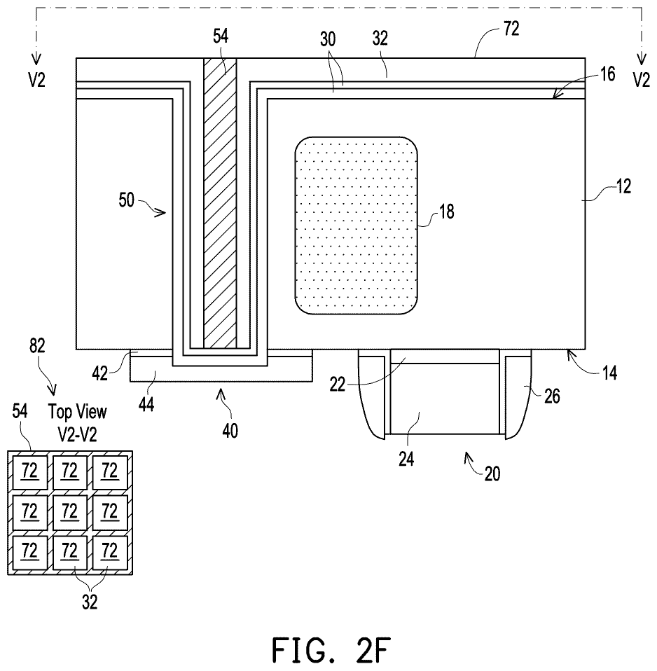

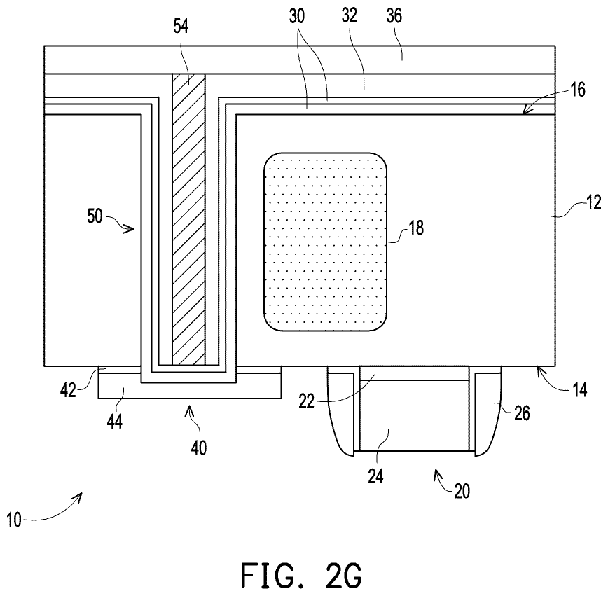

FIGS. 1A and 1B diagrammatically illustrates cut views of respective image sensor pixels 2 and 10 which employ the STI-stopped DTI 6 and DTI 50, respectively. It will be appreciated that in practice, all image sensor pixels of a two-dimensional array of image sensor pixels making up an image sensor typically employ the same type of DTI, such as all image sensor pixels of a two-dimensional array of image sensor pixels employing the DTI 50 of the image sensor pixel 10 with its DTI 50 whose metal 54 advantageously passes completely through the semiconductor substrate 12 from its first surface 14 to its second surface 16. Moreover, the DTI 50 may be formed as a DTI grid 50 (see, e.g., FIG. 2F) with each image sensor pixel 10 (including the light sensor 18 of the pixel 10) being mostly or completely surrounded or encircled by a surrounding portion of the DTI (grid) 50. This is seen in the cut view of FIG. 1B in that image sensor pixel 10 has a DTI 50 on either side thereof.

With reference now to FIGS. 2A, 2B, 2C, 2D, 2E, 2F, and 2G, a method of fabricating the image sensor pixel 10 of FIG. 1B is diagrammatically illustrated by way of successive cut views. Note that FIG. 2A illustrates two image sensor pixels under fabrication, while remaining FIGS. 2B-2G illustrate a single image sensor pixel under fabrication.

FIG. 2A illustrates two image sensor pixels under fabrication after formation of the light sensor 18 disposed in the semiconductor substrate 12, and formation of the gate oxide 22 and gate 24 of the CMOS transistor 20 on the first surface 14 of the semiconductor substrate 12. In a suitable approach, continuous oxide and polysilicon layers corresponding to the gate oxide 22 and gate 24, respectively, are deposited and patterned. As further seen in FIG. 2A, a continuous oxide layer 42L is disposed on the first surface 14 of the semiconductor substrate 12, and a continuous silicon nitride layer 44L is deposited on the continuous oxide layer 42L. Subsequent etching has removed these layers from the top of the gate 24.

FIG. 2B illustrates one image sensor pixel under fabrication after etching of the continuous oxide layer 42L and continuous silicon nitride layer 44L to isolate the oxide/silicon nitride spacers 26 of the CMOS transistor 20. The etching further leaves a portion of the continuous oxide layer 42L and continuous silicon nitride layer 44L that forms the oxide layer 42 and silicon nitride layer 44 of the etch stop 40 disposed on the first surface 14 of the semiconductor substrate 12.

The processing described with reference to FIGS. 2A and 2B is performed on the first surface (e.g., frontside) 14 of the semiconductor substrate 12. As seen in FIGS. 2A and 2B, there are no devices or other fabricated features thus far formed on the second surface (e.g., backside) 16 of the semiconductor substrate 12.

FIG. 2C illustrates one image sensor pixel under fabrication after etching a deep trench 60 starting at the second surface 16 with the etching proceeding to and stopping at the etch stop 40 disposed on the first surface 14. The etching stops at the etch stop 40, and a bottom surface 62 of the etched deep trench 60 is a surface of the etch stop 40, and in the illustrative example of FIG. 2B specifically a surface of the silicon nitride layer 44 of the etch stop 40. The deep trench 60 also has a sidewall 64, and has an opening 66 at the second surface 16.

To further visualize the geometry of the deep trench 60, a top view 70 is also shown in FIG. 2C, viewed along the direction V1-V1 indicated in the cut view of FIG. 2C. As seen in the top view 70, the deep trench 60 forms a grid, with a light-sensitive portion 72 of each image sensor pixel (including the light sensor 18 of the pixel) being mostly or completely surrounded or encircled by a surrounding portion of the deep trench 60. Put another way, the etch stop 40 is an etch stop grid 40, and the deep trench 60 is a deep trench grid 60, with cells of the deep trench grid 60 encircling respective image sensor pixels. In the top view 70, the bottom surface 62 of the trench is visible. Hence, when the deep trench grid 60 is filled with metal 54 (see FIG. 2E), the mostly or entirely encircling metal 54 of the DTI 50 forms a DTI grid 50 that provides optical isolation to suppress cross-talk between neighboring image sensor pixels.

To enable the trench 66 to be etched from the second (i.e. backside) surface 16, the semiconductor substrate 12 is suitably flipped over. For structural support, the front side 14 may optionally be bonded to a support wafer, held by adhesive tape, or otherwise supported. Although not shown, it is contemplated to first form a portion or all of a metallization of the front surface 14, e.g., comprising one or more patterned metallization layers spaced apart by intermetal dielectric (IMD) material. Such metallization of the front surface 14 may, for example, provide electrical interconnection of the MOS transistors 20 of the final image sensor.

The etching to form the deep trench 60 may, by way of nonlimiting illustrative example, employ dry etching, plasma etching, or so forth, using an etchant that selectively etches the semiconductor material of the semiconductor substrate 12 without etching the material of at least one layer of the etch stop 40 (e.g., without etching the silicon nitride layer 44 in the illustrative example). Photolithographic patterning is used to delineate the lateral area of the deep trench 60, e.g., by coating the second (e.g., backside) surface 60 with a photoresist coating, performing optical exposure of the photoresist using a photolithography mask to form a latent image of the pattern of the deep trenches 60 in and/or on the photoresist, and developing the latent image to form openings in the photoresist corresponding to the pattern of the deep trenches 60. The etching is then performed through the openings in the photoresist. Optionally, the photolithographic patterning may additionally employ one or more hard masks deposited prior to coating the photoresist and patterned during the development process, to provide sufficient mask resistance to the etchant.

FIG. 2D illustrates one image sensor pixel under fabrication after deposition of one or more dielectric layers 30, 32. In the illustrative example, these include the one or more high-k layers 30 having a dielectric constant higher than the dielectric constant of SiO₂, which in one nonlimiting illustrative example are deposited by chemical vapor deposition (CVD); and the oxide layer 32 which in one nonlimiting illustrative example is deposited by atomic layer deposition (ALD). As seen in FIG. 2D, the one or more dielectric layers 30, 32 are conformally deposited, so that they conformally coat the second surface 16 of the semiconductor substrate 12 and the bottom surface 62 and sidewall 64 of the deep trench 60. As previously noted, the one or more dielectric layers 30, 32 are relatively thin, e.g., in some nonlimiting illustrative embodiments having on the order of nanometers to tens of nanometers. Hence, the conformally coated one or more dielectric layers 30, 32 leave most of the interior volume of the deep trench 60 unfilled. That is, the one or more dielectric layers 30, 32 leave an unfilled portion of the etched deep trench 60.

FIG. 2E illustrates one image sensor pixel under fabrication after the further step of filling the unfilled portion of the etched deep trench 60 with the metal 54. In one nonlimiting illustrative embodiment, the metal 54 is copper, and the filling the unfilled portion of the etched deep trench 60 with the metal (here copper) 54 is performed by electroplating, in which a thin conformal seed copper layer is applied by CVD or the like followed by the copper electroplating.

In another nonlimiting illustrative embodiment, the metal 54 is aluminum, and the filling the unfilled portion of the etched deep trench 60 with the metal (here aluminum) 54 is performed by physical vapor deposition (PVD).

In the above examples, the etched deep trench 60 is filled with a metal, namely copper or aluminum. More generally, the etched deep trench 60 is filled with an opaque material, which is opaque for the wavelength or wavelength band or region of light to be imaged by the image sensor pixel 10.

As seen in FIG. 2E, in both electroplating and PVD, the metal deposition is not limited to the deep trench 60—rather, excess metal 80 (e.g., excess electroplated copper 80 or excess aluminum 80 deposited by PVD, in the two nonlimiting illustrative examples) coats the second surface 16 of the semiconductor substrate 12 (or, more precisely, coats the one or more dielectric layers 30, 32 previously deposited on the second surface 16 of the semiconductor substrate 12 as previously described with reference to FIG. 2D).

FIG. 2F illustrates one image sensor pixel under fabrication after a subsequent chemical mechanical polishing (CMP) step performed to remove the excess metal 80. To further visualize the geometry at this stage of the fabrication, a top view 82 is also shown in FIG. 2C, viewed along the direction V2-V2 indicated in the cut view of FIG. 2F. As seen in the top view 82, the metal 54 filling the deep trenches 60 forms a grid, with the light-sensitive portion 72 of each image sensor pixel (including the light sensor 18 of the pixel) being mostly or completely surrounded or encircled by a surrounding portion of the metal 54. In the top view 82, the light-sensitive portions 72 are coated with the one or more dielectric layers 30, 32, with the topmost dielectric layer 32 being seen in the top view 82. The encircling metal 54 of the DTI 60 provides optical isolation to suppress cross-talk between neighboring image sensor pixels. Referencing both the main cut view and the top view 82, it is seen that the DTI 50 comprises a metal barrier 54 passing through the semiconductor substrate 12 and arranged to provide optical isolation of the photodiode 18 of the image sensor pixel 10.

FIG. 2G illustrates the image sensor pixel 10 of FIG. 1B after the final optional fabrication step of deposition of the additional oxide layer 36, for example by low-temperature remote plasma-assisted oxidation (LRPO), to provide water resistance or other protection against ingress of contaminants. The additional oxide layer 36 covers the end of the metal 54 previously exposed at the second surface 16, to avoid oxidation or other degradation of the metal 54 and/or ingress of contaminants via the interface between the metal 54 and the oxide 32.

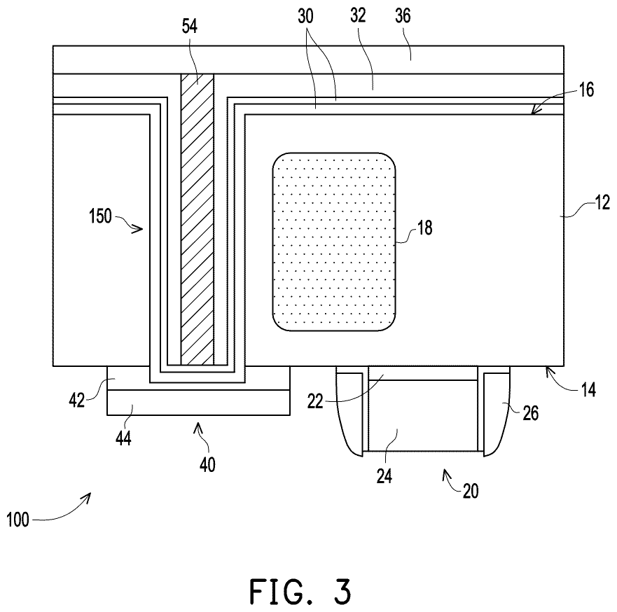

With reference now to FIG. 3, a cut view is diagrammatically illustrated of an image sensor pixel 100 according to another embodiment. The image sensor pixel 100 of FIG. 3 is similar to the image sensor pixel 10 of FIGS. 1 and 2G, and includes the semiconductor substrate 12 with opposing first and second surfaces 14 and 16, light sensor (e.g., photodiode) 18, MOS transistor 20 with components 22, 24, 26 as previously described, the one or more dielectric layers 30, 32 and additional oxide layer 36, and the etch stop 40 including oxide layer 42 disposed on the first surface 14 of the semiconductor substrate 12 and a silicon nitride layer 44 deposited on the oxide layer 42. The image sensor pixel 100 differs from the image sensor pixel 10 in that the image sensor pixel 100 has different deep trench isolation (DTI) 150 for isolating the image sensor pixel 100. While the DTI 50 of the image sensor pixel 10 of FIGS. 1 and 2G extends to the silicon nitride layer 44 of the etch stop 40, the DTI 150 of the image sensor pixel 100 of FIG. 3 extends only to the oxide layer 42 of the etch stop 40. To obtain the DTI 150 of the image sensor pixel 100, the etchant for forming the deep trench 66 (see FIG. 2C) is selected to stop at the oxide layer 42. In other words, the etchant is chosen to selectively etch the semiconductor material of the semiconductor substrate 12 without etching the oxide material of the oxide layer 42. Thus, in the image sensor pixel 100 of FIG. 3, the bottom surface of the etched deep trench 60 in fabricating the image sensor pixel 100 of FIG. 3 is a surface of the oxide layer 42.

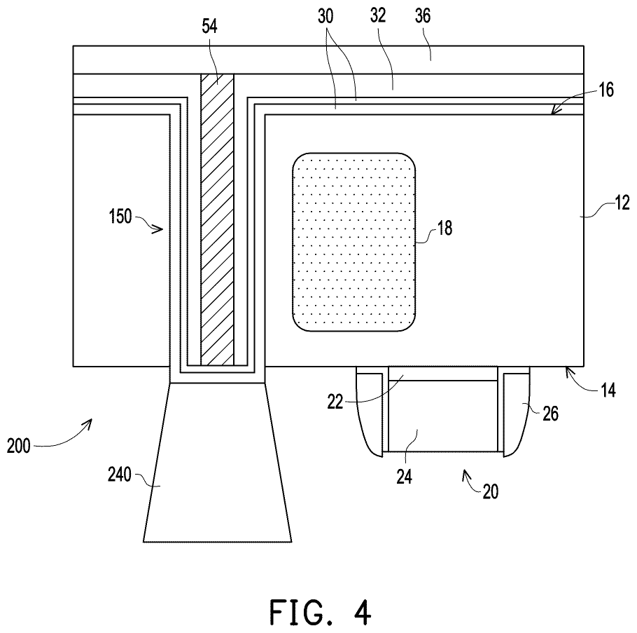

FIG. 4 diagrammatically illustrates a cut view of an image sensor pixel 200 according to another embodiment. The image sensor pixel 200 of FIG. 4 is similar to the image sensor pixel 10 of FIGS. 1 and 2G and image sensor pixel 100 of FIG. 3, and again includes the semiconductor substrate 12 with opposing first and second surfaces 14 and 16, light sensor (e.g., photodiode) 18, MOS transistor 20 with components 22, 24, 26 as previously described, the one or more dielectric layers 30, 32, and the additional oxide layer 36. The image sensor pixel 200 differs from the image sensor pixels 10 and 100 in that the image sensor pixel 200 employs a different etch stop 240 compared with the etch stop 40 of the image sensor pixels 10 and 100. The etch stop 240 is a metal via 240, which is formed on the first surface 14. For example, the metal via 240 may be a tungsten via of a metallization (not shown) of the front surface 14, e.g., comprising one or more patterned metallization layers spaced apart by IMD material. Such metallization of the front surface 14 may, for example, provide electrical interconnection of the transistors 20 of the final image sensor. The illustrated metal via 240 is a nonfunctional metal via, in that it is not part of the electrical interconnection of the transistors 20 of the final image sensor. Rather, the metal via 240 serves as an etch stop 240, insofar as etching of the deep trench 60 (see FIG. 2C) stops at the metal via 240, and the bottom surface of the etched deep trench 60 in fabricating the image sensor pixel 200 of FIG. 4 is a surface of the metal via 240. However, it is alternatively contemplated for the metal via 240 to connect with an electrical ground or with a chosen electrical potential, for example to provide electrical shielding of individual image sensor pixels, electrical manipulation of stored photocharge in the pixels, or so forth.

An advantage of the approach of FIG. 4 is that no additional processing may be required to provide the etch stop 240. Rather, the photolithographic mask used to form the lowest (i.e., M0) vias of the metallization formed on the first surface 14 is modified to provide additional openings for the etch stop 240, and the via filling for the lowest (i.e., M0) vias thus also fills the openings for the etch stop 240 with tungsten (or another metal chosen for forming the M0 vias). DTI 250 of the image sensor pixel 200 of FIG. 4 is formed the same way as the DTI 50 of the image sensor pixel 10 of FIGS. 1 and 2G, except that the etching stops at the metal via 240.

With reference now to FIG. 5, top and cut views are diagrammatically illustrated of the image sensor pixel 10 of FIGS. 1 and 2G in the context of a two-wafer stack according to an embodiment. As previously noted and as illustrated in FIG. 5, a metallization layer or stack 300 may be disposed on the frontside 14 of the image sensor comprising a two-dimensional array of the image sensor pixels 10 (one of which is shown in FIG. 5) to provide electrical transmission pathways for the pixel outputs of the electronic readout device or subcircuits 20 of the image sensor pixels 10. As seen in FIG. 5, the metallization layer or stack 300 comprises one or more metallization layer (illustrative metallization layers M1, . . . , Mx, Mz) interconnected by vias 302, with the metallization layers M1, . . . , Mx, Mz and vias 302 embedded in interlayer dielectric (ILD) 304, which is also known in the art by alternative nomenclatures such as intermetal dielectric (IMD) material 304 or the like. The metallization layer or stack 300 is suitably formed during back end-of-line (BEOL) processing, e.g., entailing iterative formation of each successive metallization layer M1, . . . , Mx, Mz and vias 302 connecting with the underlying metallization layer (or, for metallization layer M1, with the image sensor pixel 10).

In FIG. 5, the resulting wafer is labeled as wafer T1, which includes the image sensor pixels 10 fabricated in and/or on a semiconductor substrate 12, and the metallization layer or stack 300. The illustrative example of FIG. 5 further shows bonding of the wafer T1 with a second wafer T2 which includes a (second) semiconductor substrate 12′ in and/or on which electronic devices 310 are fabricated, and a (second) metallization layer or stack 300′ comprising metallization layers embedded in ILD 304′ and connected by vias 302′. A bond 320 bonds the two wafers T1 and T2 together. The illustrative bond 320 does not employ solder bonds for electrical connection, but instead employs direct bonding of copper (or other metal) pads 322 formed on the joined surfaces of the respective metallization layers or stacks 300 and 300′ (and specifically contacting the topmost Mz metallization layer). Other wafer bonding approaches, including those employing solder, are alternatively contemplated. The electronic devices 310 of the second wafer T2 can be transistors (e.g., planar, finFETs, gate-all-around i.e., GAA transistors, et cetera) or other electronic devices forming an integrated circuit (IC) implementing backend logic of the imaging sensor data storage, analog-to-digital (A/D) conversion circuitry, digital image processing (DSP), various combinations thereof, and/or so forth.

In the example of FIG. 5, the DTI grid 50 aligns with a portion of the patterned M1 metal layer, and the metal does not extend into the metallization stack 300 past the M1 metal layer. Thus, this implements a trench-type contact 234, which as seen in the top view of FIG. 5 forms a trench-type contact grid 234 surrounding the light sensor pixels (where the top view shows a portion of the trench-type contact grid 234 surrounding the illustrative light sensor 18). The trench-type contact grid 234 provides suitable light isolation for the light sensor 18 of the image sensor pixel if the light penetration depth does not extend significantly into the metallization layer or stack 300 of the first wafer T1.

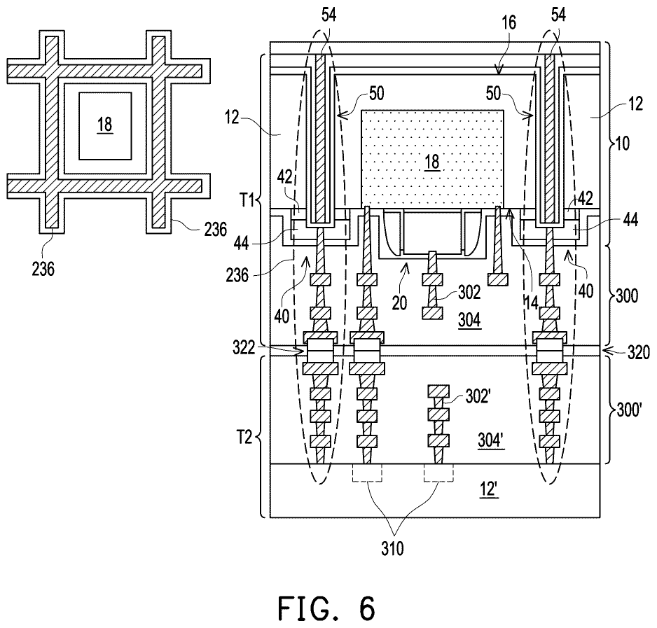

With reference now to FIG. 6, top and cut views are diagrammatically illustrated of the image sensor pixel 10 of FIGS. 1 and 2G in the context of a two-wafer stack according to a variant embodiment compared with FIG. 5. As previously illustrated in FIG. 5, this embodiment also includes the metallization layer or stack 300 on the frontside 14 of the image sensor comprising a two-dimensional array of the image sensor pixels 10 (one of which is shown in FIG. 6), the metallization layer or stack 300 comprising one or more metallization layer M1, . . . , Mx, Mz interconnected by vias 302 and embedded in interlayer dielectric (ILD) 304, as also previously described with reference to FIG. 5. As in FIG. 5, the resulting wafer T1 is bonded with the second wafer T2 which includes the (second) semiconductor substrate 12′ in and/or on which electronic devices 310 are fabricated, and the (second) metallization layer or stack 300′ comprising the metallization layers embedded in ILD 304′ and connected by the vias 302′, with the bond 320 bonding the two wafers T1 and T2 together with electrical contacts implemented by direct bonding of metal pads 322 formed on the joined surfaces of the respective metallization layers or stacks 300 and 300′.

In the example of FIG. 6, the DTI grid 50 aligns with a portion of the patterned M1 metal layer, and the metal extends into the metallization stack 300 past the M1 metal layer, through the subsequent patterned metal layers Mx, . . . , Mz to the metal pads 322, where it connects with further metallization in the metallization stack 300′ of the second wafer T2 which extends through the patterned metal layers Mz, . . . , Mx, . . . , M1 of the metallization stack 300′ of the second wafer T2. Thus, this implements a grid-type contact 236 extending through both metallization stacks 300 and 300′ formed during the BEOL processing of the respective two wafers T1 and T2. As seen in the top view of FIG. 6 this forms a contact grid 236 surrounding the light sensor pixels (where the top view of FIG. 6 shows a portion of the contact grid 236 surrounding the illustrative light sensor 18). The contact grid 236 provides suitable light isolation for the light sensor 18 of the image sensor pixel even if the light penetration depth extend significantly into the metallization layer or stack 300 of the first wafer T1, and even if the light penetrates significantly into the metallization layer or stack 300′ of the second wafer T2. The contact grid 236 may be electrically nonfunctional, in that it is not electrically biased. Rather, the contact grid 236 serves only as an optical crosstalk barrier as just described. However, it is alternatively contemplated for the contact grid 236 to connect with an electrical biasing circuit (not shown) in the second wafer T2, for example to electrically ground the contact grid 236, or to apply a chosen electrical potential to the contact grid 236, for example to provide electrical shielding of individual image sensor pixels, electrical manipulation of stored photocharge in the pixels, or so forth.

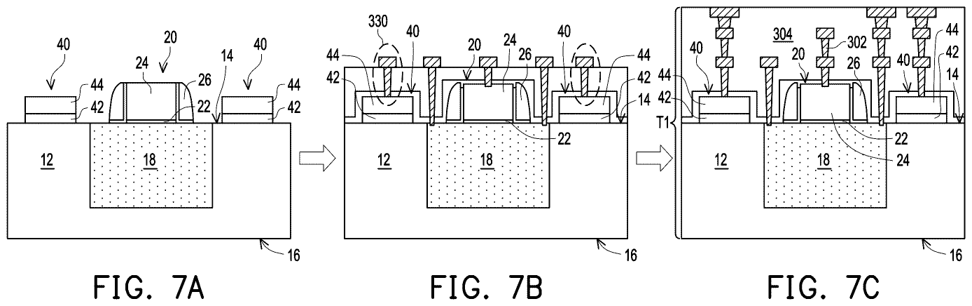

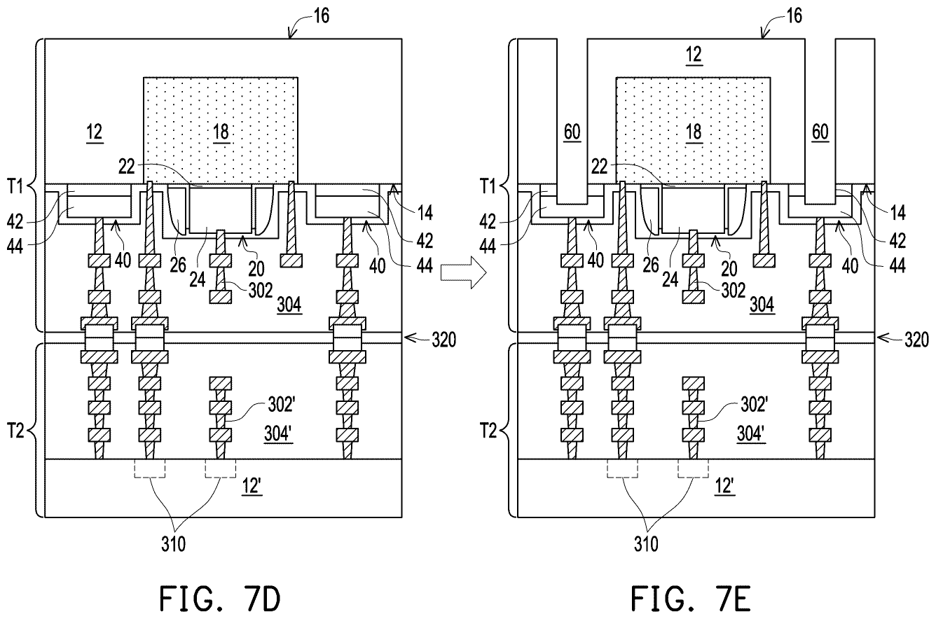

With reference to FIGS. 7A, 7B, 7C, 7D, and 7E, a method of fabricating the two-wafer stack of FIG. 6 is diagrammatically illustrated. FIG. 7A illustrates the fabricated image sensor pixel 10. This corresponds to FIG. 2B of the processing sequence of FIGS. 2A, 2B, 2C, 2D, 2E, 2F, and 2G, and includes the sidewall (SW) 26 formed of the oxide and silicon nitride layers 42, 44 which also form the etch stop 40.

FIG. 7B illustrates the initial phase of BEOL processing on the frontside 14 of the image sensor to form the first portion of the ILD 304 and the patterned M1 metallization layer connected with the image sensor pixel by vias, which also forms a contact 330 on the etch stop 40. FIG. 7C illustrates further BEOL processing on the frontside 14 of the image sensor to form the subsequent metallization layers Mx, . . . , Mz. FIG. 7D illustrates the wafer T1 bonded to the second wafer T2 by the bond 320.

Notably, at the fabrication stage shown in FIG. 7D, the backside 16 of the semiconductor substrate 12 of image sensor pixel is exposed, with the wafer T1 (which may optionally have been thinned during fabrication of the image sensor pixel) being supported on the second wafer T2. Hence, the backside 16 is exposed to perform the remaining backside processing previously described with reference to FIGS. 2C, 2D, 2E, 2F, and 2G, To illustrate this, FIG. 7E illustrates the image sensor pixel under fabrication after etching the deep trench 60 starting at the second surface 16 (i.e., backside 16) with the etching proceeding to and stopping at the etch stop 40 disposed on the first surface 14 (i.e., frontside 14). Thus, FIG. 7E corresponds to FIG. 2C. By performing the further backside processing previously described with reference to FIGS. 2D-2G, the final image sensor pixel shown in FIG. 6 is obtained.

FIGS. 5 and 6 illustrate examples of a two-wafer stack including the wafer T1 comprising the image sensor bonded to a second wafer T2 which may provide image sensor driving circuitry or the like comprising the devices 310 formed in and/or on the semiconductor substrate 12′ of the second wafer T2. It will be appreciated that such wafer stacking can be extended to three (or more) wafers, with the wafer T1 comprising the image sensor being a topmost wafer of the stack in order to receive the light.

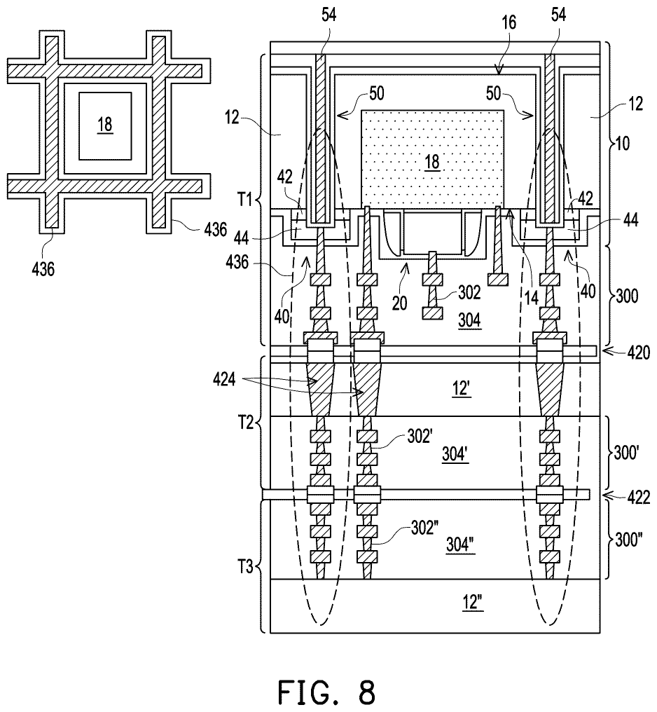

With reference to FIG. 8, top and cut views are diagrammatically illustrated of the image sensor pixel of FIGS. 1 and 2G in the context of a three-wafer stack including the wafer T1 comprising the image sensor, a second wafer T2, and a third wafer T3. This example also differs from that of FIGS. 5 and 6 in that the wafer T1 comprising the image sensor is bonded to the backside of the second wafer T2, i.e., to the backside of the semiconductor substrate 12′ opposite from the metallization stack 300 formed by the BEOL processing of the first wafer T1. Thus, a bond 420 is formed between the metallization stack 300 of the first wafer T1 and the backside of the semiconductor substrate 12′ of the second wafer T2. A further bond 422 is formed between the metallization stack 300′ formed on the frontside of the second wafer T2 and a metallization stack 300″ formed on the frontside of the third wafer T3 (where again the metallization stack 300″ is formed on a semiconductor substrate 12″ of the third wafer T3 during BEOL processing of the third wafer T3). The second wafer T2 includes through substrate vias (TSVs) 424 passing through the semiconductor substrate 12′ to enable electrical connection between the metallization stack 300 of the first wafer T1 and the metallization stack 300′ of the formed on the frontside of the second wafer T2. If the semiconductor substrate 12′ is a silicon wafer, then the TSVs 424 may be considered through-silicon vias (TSVs).

In the example of FIG. 8, the DTI grid 50 aligns with a portion of the patterned M1 metal layer, and the metal extends into the metallization stack 300 past the M1 metal layer, through the subsequent patterned metal layers Mx, . . . , Mz to the metal pads 322, where it connects with further metallization in the metallization stack 300′ of the second wafer T2 which extends through the patterned metal layers Mz, . . . , Mx, . . . , M1 of the metallization stack 300′ of the second wafer T2. In this example, the contact grid further connects with still further metallization in the metallization stack 300″ of the third wafer T3 which extends through the patterned metal layers Mz, . . . , Mx, . . . , M1 of the metallization stack 300″ ‘of the third wafer T3. Thus, this implements a grid-type contact 236 extending through all three metallization stacks 300, 300′, and 300″ formed during the BEOL processing of the respective three wafers T1, T2, and T3. As seen in the top view of FIG. 8 this forms a contact grid 436 surrounding the light sensor pixels (where the top view of FIG. 8 shows a portion of the contact grid 436 surrounding the illustrative light sensor 18). The contact grid 436 provides suitable light isolation for the light sensor 18 of the image sensor pixel even if the light penetration depth extends all the way into the metallization layer or stack 300″ of the third wafer T3. The contact grid 436 may be electrically nonfunctional, in that it is not electrically biased. Rather, the contact grid 436 serves only as an optical crosstalk barrier as just described. However, it is alternatively contemplated for the contact grid 436 to connect with an electrical biasing circuit (not shown) in the third wafer T3, for example to electrically ground the contact grid 436, or to apply a chosen electrical potential to the contact grid 436, for example to provide electrical shielding of individual image sensor pixels, electrical manipulation of stored photocharge in the pixels, or so forth.

In the following, some further embodiments are described.

In a nonlimiting illustrative embodiment, a method includes: disposing an etch stop on a first surface of a semiconductor substrate; etching a deep trench from a second surface, on an opposite side of the semiconductor substrate from the first surface, to the etch stop disposed on the first surface, wherein the etching stops at the etch stop and a bottom surface of the etched deep trench is a surface of the etch stop; depositing at least one dielectric layer on a sidewall and the bottom surface of the etched deep trench, the at least one dielectric layer leaving an unfilled portion of the etched deep trench; and filling the unfilled portion of the etched deep trench with a metal. In some embodiments, the method is performed to isolate an image sensor pixel comprising a light sensor disposed in the semiconductor substrate.

In a nonlimiting illustrative embodiment, a method is disclosed of isolating image sensor pixels of an array of image sensor pixels, each image sensor pixel comprising a light sensor disposed in a semiconductor substrate. The method includes forming an etch stop grid on a surface of the semiconductor substrate, etching a deep trench grid through the entire thickness of the semiconductor substrate using the etch stop grid to stop the etching, and disposing an opaque material in the etched deep trench grid.

In a nonlimiting illustrative embodiment, a method includes forming an etch stop grid on a surface of a semiconductor substrate, etching a deep trench grid through the entire thickness of the semiconductor substrate using the etch stop grid to stop the etching, cells of the deep trench grid encircling respective image sensor pixels of an array of image sensor pixels, and disposing an opaque material in the etched deep trench grid.

In a nonlimiting illustrative embodiment, an image sensor pixel includes: a semiconductor substrate having a first surface and a second surface opposite from the first surface; a photodiode disposed in the semiconductor substrate; and a metal barrier passing through the semiconductor substrate and arranged to provide optical isolation of the photodiode.

In a nonlimiting illustrative embodiment, an image sensor pixel includes a light sensor disposed in a semiconductor substrate. To provide isolation to reduce interpixel crosstalk and increase Modulation Transfer Function (MTF), an etch stop is disposed on a first surface of the semiconductor substrate, and a deep trench is etched from an opposite second surface to the etch stop disposed on the first surface. The etching stops at the etch stop, and a bottom surface of the etched deep trench is a surface of the etch stop. At least one dielectric layer is deposited on a sidewall and the bottom surface of the etched deep trench, and the remainder of the etched deep trench is filled with a metal, for example by copper electroplating or aluminum via physical vapor deposition

In a nonlimiting illustrative embodiment, an image sensor pixel includes a light sensor disposed in a semiconductor substrate. To provide isolation to reduce interpixel crosstalk and increase Modulation Transfer Function (MTF), an etch stop is disposed on a first surface of the semiconductor substrate, and a deep trench is etched from an opposite second surface to the etch stop disposed on the first surface. The etching stops at the etch stop, and a bottom surface of the etched deep trench is a surface of the etch stop. At least one dielectric layer may be deposited on a sidewall and the bottom surface of the deep trench, and the remainder of the deep trench is/filled with a metal or other opaque material. An image sensor pixel includes a semiconductor substrate and a photodiode disposed therein, and a metal barrier passing through the semiconductor substrate and arranged to provide optical isolation of the photodiode.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
disposing an etch stop on a first surface of a semiconductor substrate;
etching a deep trench from a second surface, on an opposite side of the semiconductor substrate from the first surface, to the etch stop disposed on the first surface, wherein the etching stops at the etch stop and a bottom surface of the etched deep trench is a surface of the etch stop;
depositing at least one dielectric layer on a sidewall and the bottom surface of the etched deep trench, the at least one dielectric layer leaving an unfilled portion of the etched deep trench; and
filling the unfilled portion of the etched deep trench with a metal.

2. The method of claim 1, wherein the disposing of the etch stop includes:
depositing at least one dielectric layer on the first surface of the semiconductor substrate.

3. The method of claim 2, wherein the at least one dielectric layer comprises a silicon nitride layer deposited on the first surface of the semiconductor substrate, and the etching stops at the silicon nitride layer and the bottom surface of the etched deep trench is a surface of the silicon nitride layer; or
wherein the at least one dielectric layer comprises an oxide layer disposed on the first surface of the semiconductor substrate and a silicon nitride layer deposited on the oxide layer, and the bottom surface of the etched deep trench is a surface of the oxide layer.

4. The method of claim 1, wherein the disposing of the etch stop includes:
forming a metal via on the first surface of the semiconductor substrate, wherein the etching stops at the metal via and a bottom surface of the etched deep trench is a surface of the metal via.

5. The method of claim 4, wherein the metal via is a tungsten via.

6. The method of claim 1, wherein the disposing of the etch stop on the first surface of the semiconductor substrate does not include etching a trench in the first surface of the semiconductor substrate.

7. The method of claim 1, wherein the depositing of the at least one dielectric layer on the sidewall and the bottom surface of the etched deep trench includes:
depositing a high-k dielectric layer on the sidewall and the bottom surface of the etched deep trench; and
depositing an oxide layer by atomic layer deposition on the high-k dielectric layer.

8. The method of claim 1, wherein the filling of the unfilled portion of the etched deep trench comprises:
performing electroplating to fill the unfilled portion of the etched deep trench with metal, with excess metal being electroplated on the second surface of the semiconductor substrate; and
performing chemical mechanical polishing of the second surface to remove the excess metal from the second surface of the semiconductor substrate.

9. The method of claim 1, wherein the filling of the unfilled portion of the etched deep trench comprises:
performing physical vapor deposition of aluminum to fill the unfilled portion of the etched deep trench with aluminum with excess aluminum being deposited on the second surface of the semiconductor substrate; and
performing chemical mechanical polishing of the second surface to remove the excess aluminum from the second surface of the semiconductor substrate.

10. The method of claim 1, wherein the deep trench passes completely through the semiconductor substrate from the second side to the first side.

11. The method of claim 1, further comprising:
after the filling of the unfilled portion of the etched deep trench, depositing an oxide layer on the second surface of the semiconductor substrate by low-temperature remote plasma-assisted oxidation.

12. A method comprising:
forming an etch stop grid on a surface of a semiconductor substrate;
etching a deep trench grid through the entire thickness of the semiconductor substrate using the etch stop grid to stop the etching, cells of the deep trench grid encircling respective image sensor pixels of an array of image sensor pixels; and
disposing an opaque material in the etched deep trench grid.

13. The method of claim 12, wherein the forming of the etch stop grid includes:
depositing at least one dielectric layer on the first surface of the semiconductor substrate, the deposited at least one dielectric layer serving as the etch stop to stop the etching.

14. The method of claim 12, wherein the forming of the etch stop grid includes:
forming a metal via grid on the first surface of the semiconductor substrate, the metal via grid serving as the etch stop to stop the etching.

15. The method of claim 12, wherein the forming of the etch stop grid does not include forming shallow trench isolation in the surface of the semiconductor substrate.

16. The method of claim 12, wherein the disposing includes:
coating a sidewall and bottom of the deep trench grid with at least one dielectric layer; and
after the coating, filling the deep trench grid with the opaque material.

17. The method of claim 12, wherein the filling includes one of:
performing electroplating to fill the deep trench grid with metal; or
performing physical vapor deposition of a metal to fill the deep trench grid with the metal.

18. An image sensor pixel comprising:
a semiconductor substrate having a first surface and a second surface opposite from the first surface;
a photodiode disposed in the semiconductor substrate; and
a metal barrier passing through the semiconductor substrate and arranged to provide optical isolation of the photodiode.

19. The image sensor pixel of claim 18, wherein the metal barrier is in contact with a dielectric layer disposed on the first surface of the substrate.

20. The image sensor pixel of claim 18, wherein the metal barrier has a thickness equal to or greater than a thickness of the substrate.
